(19) United States
(12) Patent Application Publication
(10) Pub. No.: US 2013/0157415 A1
(43) Pub. Date: Jun. 20, 2013

(54) METHOD FOR PRODUCING SEMICONDUCTOR DEVICE

(71) Applicant: NITTO DENKO CORPORATION, Osaka (JP)

(72) Inventors: Kosuke Morita, Ibaraki-shi (JP); Naohide Takamoto, Ibaraki-shi (JP); Hiroyuki Senzai, Ibaraki-shi (JP)

(73) Assignee: NITTO DENKO CORPORATION, Osaka (JP)

(21) Appl. No.: 13/715,996

(22) Filed: Dec. 14, 2012

(30) Foreign Application Priority Data
Dec. 16, 2011 (JP) 2011-275995
Dec. 16, 2011 (JP) 2011-275997
Dec. 16, 2011 (JP) 2011-276003

(51) Int. Cl. H01L 21/78

(52) U.S. Cl. CPC H01L 21/78
USPC 438/113

(57) ABSTRACT

There is provided a method for producing a semiconductor device, capable of suppressing generation of voids at an interface between a semiconductor element and an under-fill sheet to produce a semiconductor device with high reliability. The method includes providing a sealing sheet having a support and an under-fill material laminated on the support; thermally pressure-bonding a circuit surface of a semiconductor wafer, on which a connection member is formed, and the under-fill material of the sealing sheet under conditions of a reduced-pressure atmosphere of 10000 Pa or less, a bonding pressure of 0.2 MPa or more and a heat pressure-bonding temperature of 40° C. or higher; dicing the semiconductor wafer to form a semiconductor element with the under-fill material; and electrically connecting the semiconductor element and the adherend through the connection member while filling a space between the adherend and the semiconductor element using the under-fill material.

### BACKGROUND OF THE INVENTION

1. Field of the Invention

The present invention relates to a method for producing a semiconductor device.

2. Description of the Related Art

In recent years, demands for high-density mounting have been increased as electronic instruments have become smaller and thinner. For meeting the demands, a method is employed in which a back surface (surface opposite to a circuit surface on which a pattern is formed) of a semiconductor wafer is ground to make a semiconductor device thinner. Back surface grinding of the semiconductor wafer is carried out generally by bonding a back surface grinding tape to the circuit surface of the semiconductor wafer and subjecting the back surface of the semiconductor wafer to grind processing.

On the other hand, for semiconductor packages, the surface mount method has become mainstream suitable for high-density mounting in place of the conventional pin insertion method. In the surface mount method, a lead is soldered directly to a printed circuit board or the like. For a heating method, the entire package is heated by infrared reflow, vapor phase reflow, solder dip or the like to perform mounting.

After surface mounting, a sealing resin is filled in a space between a semiconductor element and a substrate for ensuring protection of the surface of the semiconductor element and connection reliability between the semiconductor element and the substrate. As this sealing resin, a liquid sealing resin is widely used, but it is difficult to adjust an injection position and an injection amount with the liquid sealing resin. Thus, there has been proposed a technique of filling a space between a semiconductor element and a substrate using a sheet-like sealing resin (an under-fill sheet) JP-B1-4438973).

Generally, in a process using an under-fill sheet, a procedure is employed in which a semiconductor element is connected to an adherend such as a substrate to be mounted while filling a space between the adherend and the semiconductor element using the under-fill sheet bonded to the semiconductor element. In the process, a space between the adherend and the semiconductor element is easily filled.

### SUMMARY OF THE INVENTION

However, in the process described above, consideration should be given to the following matters.

First, in the process described above, a circuit surface of a semiconductor wafer and an under-fill sheet are bonded together, and therefore the under-fill sheet is required to closely contact the surface of the semiconductor wafer by following raised and recessed portions thereof. However, as the number of spacing structures such as a bump on the semiconductor wafer increases and circuits become smaller, the degree of adhesion of the under-fill sheet to the semiconductor wafer decreases, so that voids (air bubbles) are generated in between the semiconductor wafer and the under-fill sheet in some cases. If air bubbles are present at an interface between the semiconductor wafer and the under-fill material, air bubbles may expand when a decompressing treatment or a heating treatment is carried out in subsequent steps, thereby reducing adhesion between the semiconductor wafer and the under-fill material, and resultantly the connection reliability between the semiconductor element and the adherend may be decreased when the semiconductor element is mounted on the adherend. If moisture at the time of back surface grinding or dicing of the semiconductor wafer are immixed into air bubbles, the moisture may be vaporized to grow or expand air bubbles when a heating step is subsequently carried out, thereby again decreasing the connection reliability between the semiconductor element and the adherend.

Second, for improving the efficiency of a series of steps from back surface grinding or dicing of the semiconductor wafer up to filling of the space between the semiconductor element and the adherend, the present inventors have tried to develop a technique of combining a back surface grinding tape with an under-fill sheet and a technique of combining a dicing tape with an under-fill sheet. In this technique, a circuit surface of a semiconductor wafer and an under-fill sheet are bonded together, and therefore the under-fill sheet is required to closely contact the surface of the semiconductor wafer by following raised and recessed portions thereof. However, as the number of spacing structures such as a bump on the semiconductor wafer increases and circuits become smaller, the degree of adhesion of the under-fill sheet to the semiconductor wafer decreases, so that voids (air bubbles) are generated in between the semiconductor wafer and the under-fill sheet in some cases. If air bubbles are present at an interface between the semiconductor wafer and the under-fill material, air bubbles may expand when a decompressing treatment or a heating treatment is carried out in subsequent steps, thereby reducing adhesion between the semiconductor wafer and the under-fill material, and resultantly the connection reliability between the semiconductor element and the adherend may be decreased when the semiconductor element is mounted on the adherend. If moisture at the time of back surface grinding or dicing of the semiconductor wafer are immixed into air bubbles, the moisture may be vaporized to grow or expand air bubbles when a heating step is subsequently carried out, thereby again decreasing the connection reliability between the semiconductor element and the adherend.

An object of the present invention is to provide a method for producing a semiconductor device, by which a semiconductor device having a high reliability can be produced by suppressing generation of voids at an interface between a semiconductor element and an under-fill sheet.

As a result of conducting vigorous studies on the first matter described above, the present inventors have found that the aforementioned object can be achieved by employing the following configuration.

That is, the present invention is a method for producing a semiconductor device having an adherend, a semiconductor element electrically connected to the adherend, and an under-fill material for filling a space between the adherend and the semiconductor element, in which the method includes:

a providing step of providing a sealing sheet having a support and an under-fill material laminated on the support;

a heat pressure-bonding step of thermally pressure-bonding a circuit surface of a semiconductor wafer, on which a connection member is formed, and the under-fill material of the sealing sheet under conditions of a reduced-pressure atmosphere of 10000 Pa or less, a bonding pressure of 0.2 MPa or more and a heat pressure-bonding temperature of 40° C. or higher;

a dicing step of dicing the semiconductor wafer to form a semiconductor element with the under-fill material; and

a connection step of electrically connecting the semiconductor element and the adherend through the connection member while filling a space between the adherend and the semiconductor element using the under-fill material.

In the production method, the circuit surface of the semiconductor wafer and the under-fill material are bonded together under specific heat pressure-bonding conditions of a reduced-pressure atmosphere of 10000 Pa or less, a bonding pressure of 0.2 MPa or more and a heat pressure-bonding temperature of 40° C. or higher, and therefore existence of a gas at an interface between the semiconductor wafer and the under-fill material can be considerably reduced to improve adhesion, whereby generation of voids at the interface can be suppressed. As a result, a semiconductor device excellent in connection reliability between a semiconductor wafer and an adherend can be efficiently produced.

In the production method, it is preferable that substantially no air bubbles should be present at an interface between the semiconductor wafer and the under-fill material (hereinafter, referred to merely as “interface” in some cases) after the bonding step. Consequently, adhesion between the semiconductor wafer and the under-fill material increases, so that the connection reliability of the semiconductor device can be further improved. In the specification, the phrase “substantially no air bubbles are present” refers to a state in which air bubbles cannot be visually observed when the pressure is reduced to a predeterminate pressure for bonding in a bonding step, and means that air bubbles having a maximum diameter of 1 mm or more are not present.

In the production method, the heat pressure-bonding step is preferably carried out under conditions of a reduced-pressure atmosphere of 10 to 10000 Pa, a bonding pressure of 0.2 to 1 MPa and a heat pressure-bonding temperature of 40 to 120° C. Consequently, gas at the interface can be sufficiently eliminated, and also deformation of the under-fill material and unprepared penetration of the connection member into the under-fill material can be prevented.

The melt viscosity of the under-fill material at the heat pressure-bonding temperature before heat curing is preferably 20000 Pa·s or less. Consequently, penetration of the connection member into the under-fill material can be facilitated at the time of heat pressure-bonding step. In addition, generation of voids at the time of electrical connection of the semiconductor element, and protrusion of the under-fill material from a space between the semiconductor element and the adherend can be prevented. Measurement of the melt viscosity is based on the procedure described in the Examples.

The under-fill material preferably contains a thermoplastic resin and a thermosetting resin. Above all, preferably the thermoplastic resin contains an acrylic resin, and the thermosetting resin contains an epoxy resin and a phenol resin. A plasticity, a strength, and a tackiness required for improving the adhesion of the under-fill material to the semiconductor wafer in the heat pressure-bonding step can be imparted to the under-fill material with good balance.

In the production method, the ratio of the thickness T (μm) of the under-fill material to the height H (μm) of the connection member (T/H) is preferably 0.5 to 2. The thickness T (μm) of the under-fill material and the height H (μm) of the connection member satisfy the above-mentioned relationship, whereby a space between the semiconductor element and the adherend can be sufficiently filled, excessive protrusion of the under-fill material from the space can be prevented, so that contamination of the semiconductor element by the under-fill material, and the like can be prevented. Even if the absolute value of the height H of the connection member is larger than the absolute value of the thickness T of the under-fill material, electrical connection of the semiconductor element and the adherend can be satisfactorily performed as long as the above-mentioned relationship is satisfied because the height H of the connection member becomes lower as the connection member is melted at the time of mounting.

In the production method, the support may be a base material. The support may also be a back surface grinding tape or dicing tape including a base material and a pressure-sensitive adhesive layer laminated on the base material. The back surface grinding tape or dicing tape and the under-fill material are integrated, whereby a space between the semiconductor element and the adherend can be easily filled while tightly holding the semiconductor wafer at the time of back surface grinding or dicing of the semiconductor wafer, so that steps from back surface grinding or dicing up to filling at the time of electrical connection can be efficiently performed in production of a semiconductor device.

As a result of conducting vigorous studies on the second matter described above, the present inventors have found that the aforementioned object can be achieved by employing the following configuration.

That is, the present invention is a method for producing a semiconductor device having an adherend, a semiconductor element electrically connected to the adherend, and an under-fill material for filling a space between the adherend and the semiconductor element, in which the method includes:

a providing step of providing a sealing sheet having a back surface grinding tape and an under-fill material laminated on the back surface grinding tape;

a bonding step of bonding a circuit surface of a semiconductor wafer, on which a connection member is formed, and the under-fill material of the sealing sheet under a reduced pressure of 1000 Pa or less;

a grinding step of grinding a surface of the semiconductor wafer opposite to the circuit surface;

a dicing step of dicing the semiconductor wafer to form a semiconductor element with the under-fill material; and

a connection step of electrically connecting the semiconductor element and the adherend through the connection member while filling a space between the adherend and the semiconductor element using the under-fill material.

Further, the present invention is a method for producing a semiconductor device having an adherend, a semiconductor element electrically connected to the adherend, and an under-fill material for filling a space between the adherend and the semiconductor element, in which the method includes:

a providing step of providing a sealing sheet having a dicing tape and an under-fill material laminated on the dicing tape;

a bonding step of bonding a circuit surface of a semiconductor wafer, on which a connection member is formed, and the under-fill material of the sealing sheet under a reduced pressure of 1000 Pa or less;

a dicing step of dicing the semiconductor wafer to form a semiconductor element with the under-fill material; and

a connection step of electrically connecting the semiconductor element and the adherend through the connection member while filling a space between the adherend and the semiconductor element using the under-fill material.

In the production method, the circuit surface of the semiconductor wafer and the under-fill material are bonded together under a reduced pressure of 1000 Pa or less, and therefore existence of a gas at an interface between the semiconductor wafer and the under-fill material can be considerably reduced to improve adhesion, whereby generation of voids at the interface can be suppressed. As a result, a semiconductor device excellent in connection reliability between a semiconductor wafer and an adherend can be efficiently produced. In addition, the back surface grinding tape and the under-fill material are integrated or the dicing tape and the under-fill material are integrated, and therefore the semiconductor wafer at the time of back surface grinding or dicing of the semiconductor wafer can be tightly held, and a space between the semiconductor element and the adherend can be easily filled, so that steps from back surface grinding or dicing up to filling at the time of electrical connection can be efficiently performed in production of a semiconductor device.

In the production method, it is preferable that substantially no air bubbles should be present at an interface between the semiconductor wafer and the under-fill material (hereinafter, referred to merely as “interface” in some cases) after the bonding step. Consequently, adhesion between the semiconductor wafer and the under-fill material increases, so that the connection reliability of the semiconductor device can be further improved. In the specification, the phrase “substantially no air bubbles are present” refers to a state in which air bubbles cannot be visually observed when the pressure is reduced to a predeterminate pressure for bonding in a bonding step, and means that air bubbles having a maximum diameter of 1 mm or more are not present.

In the production method, the connection step preferably includes the steps of: contacting the connection member and the adherend with each other under a temperature a of the following requirement (1); and fixing the contacted connection member to the adherend under a temperature β of the following requirement (2):

Requirement (1): melting point of connection member−100° C.≦α<melting point of connection member

Requirement (2): melting point of connection member≦β≦melting point of connection member+100° C.

By employment of a connection step including the predetermined steps described above, first the connection member of the semiconductor element and the adherend are contacted with each other under heating at a predetermined temperature α, which is lower than the melting point of the connection member, at the time of electrically connecting the semiconductor element and the adherend. Consequently, the under-fill material is softened, so that penetration of the connection member into the under-fill material can be facilitated, and contact of the connection member and the adherend can be kept at an adequate level. In this state, the connection member and the adherend are fixed to each other at a predetermined temperature β, which is equal to or higher than the melting point of the connection member, to obtain electrical connection, and therefore a semiconductor device having high connection reliability can be efficiently produced.

In the production method, the minimum melt viscosity of the under-fill material at 100 to 200° C. before heat curing is preferably 100 Pa·s or more and 20000 Pa·s or less. Consequently, penetration of the connection member into the under-fill material can be facilitated. In addition, generation of voids at the time of electrical connection of the semiconductor element, and protrusion of the under-fill material from a space between the semiconductor element and the adherend can be prevented. Measurement of the minimum melt viscosity is based on the procedure described in the Examples.

In the production method, the viscosity of the under-fill material at 23° C. before heat curing is preferably 0.01 MPa·s or more and 100 MPa·s or less. The under-fill material before heat curing has such a viscosity, whereby the retention property of a semiconductor wafer at the time of dicing and the handling property at the time of operation can be improved.

### BRIEF DESCRIPTION OF THE DRAWINGS

FIG. 1 is a sectional schematic view showing a sealing sheet according to one embodiment of the present invention;

FIG. 2A is a sectional schematic view showing a step for producing a semiconductor device according to one embodiment of the present invention;

FIG. 2B is a sectional schematic view showing a step for producing a semiconductor device according to one embodiment of the present invention;

FIG. 2C is a sectional schematic view showing a step for producing a semiconductor device according to one embodiment of the present invention;

FIG. 2D is a sectional schematic view showing a step for producing a semiconductor device according to one embodiment of the present invention; and

FIG. 2E is a sectional schematic view showing a step for producing a semiconductor device according to one embodiment of the present invention.

### DETAILED DESCRIPTION OF THE PREFERRED EMBODIMENTS

### First Embodiment

### Providing Step

In a providing step, a sealing sheet including a support and an under-fill material laminated on the support is provided. As the support, a base material, a back surface grinding tape, a dicing tape or the like can be suitably used. This embodiment will be described taking as an example a case where a back surface grinding tape is used.

### (Sealing Sheet)

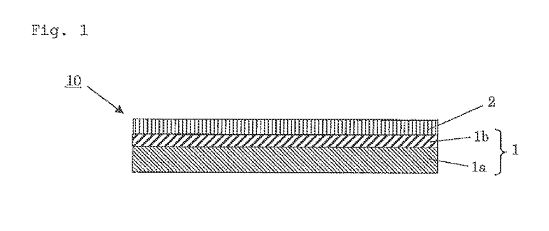

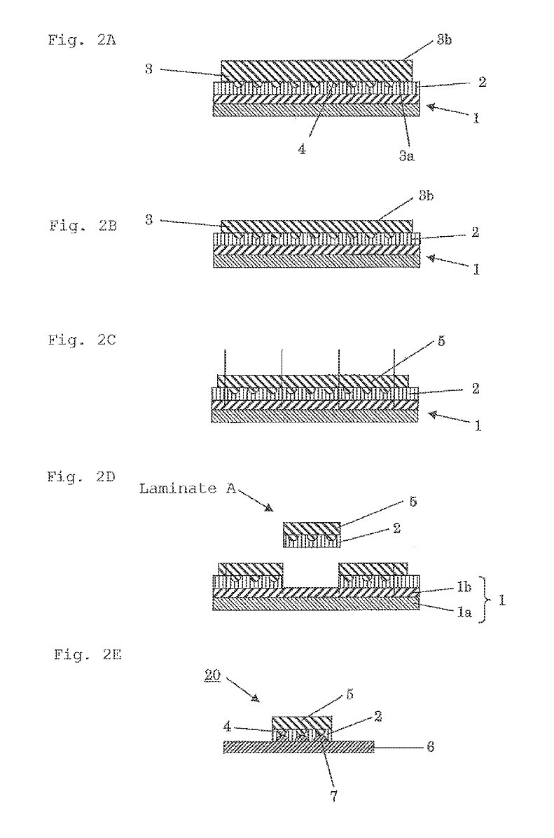

As shown in FIG. 1, a sealing sheet 10 includes aback surface grinding tape 1 and an under-fill material 2 laminated on the back surface grinding tape 1. The under-fill material 2 is not necessarily laminated on the entire surface of the back surface grinding tape 1 as shown in FIG. 1, but may be provided in a size sufficient for bonding with a semiconductor wafer 3 (see FIG. 2A).

### (Back Surface Grinding Tape)

The back surface grinding tape 1 includes a base material 1a and a pressure-sensitive adhesive layer 1b laminated on the base material 1a. The under-fill material 2 is laminated on the pressure-sensitive adhesive layer 1b.

### (Base Material)

The base material 1a is a reinforcement matrix for the sealing sheet 10. Examples of the material thereof include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, aramid (paper), glass, glass cloth, a fluororesin, polyvinyl chloride, polyvinylidene chloride, a cellulose-based resin, a silicone resin, a metal (foil), and papers.

When the pressure-sensitive adhesive layer 1b is of an ultraviolet-ray curable-type, the base material 1a is preferably one having a permeability to ultraviolet rays.

In addition, examples of the material of the base material 1a include polymers such as crosslinked products of the resins described above. For the plastic film described above, an unstretched film may be used, or a film subjected to uniaxial or biaxial stretching may be used as necessary.

The surface of the base material 1a can be subjected to a common surface treatment, for example, a chemical or physical treatment such as a chromic acid treatment, ozone exposure, flame exposure, high-voltage electrical shock exposure or an ionized radiation treatment, or a coating treatment with a primer (e.g. adhesive substance to be described) for improving adhesion with an adjacent layer, the retention property and so on.

For the base material 1a, the same material or different materials can be appropriately selected and used, and one obtained by blending several materials can be used as necessary. The base material 1a can be provided thereon with a vapor-deposited layer of an electrically conductive substance made of a metal, an alloy, an oxide thereof, or the like and having a thickness of about 30 to 500 Å for imparting an antistatic property. The base material 1a may be a single layer or a multiple layer having two or more layers.

The thickness of the base material 1a can be appropriately determined, and is generally about 5 μm or more and 200 μm or less, and is preferably 35 μm or more and 120 μm or less.

The base material 1a may contain various kinds of additives (e.g. colorant, filler, plasticizer, anti-aging agent, antioxidant, surfactant, flame retardant, etc.) within the bounds of not impairing the effect of the present invention.

### (Pressure-Sensitive Adhesive Layer)

A pressure-sensitive adhesive used for forming the pressure-sensitive adhesive layer 1b is not particularly limited as long as it can tightly hold a semiconductor wafer or a semiconductor chip through an under-fill material at the time of back surface grinding and dicing, and provide control so that the semiconductor chip with the under-fill material can be peeled off during pickup. For example, a general pressure-sensitive adhesive such as an acryl-based pressure-sensitive adhesive or a rubber-based pressure-sensitive adhesive can be used. As the pressure-sensitive adhesive, an acryl-based pressure-sensitive adhesive having an acryl-based polymer as a base polymer is preferable for ease of cleaning of an electronic component sensitive to contamination, such as a semiconductor wafer or glass, using ultrapure water or an organic solvent such as an alcohol.

Examples of the acryl-based polymer include those using an acrylic acid ester as a main monomer component. Examples of the acrylic acid ester include one or more of, for example (meth) acrylic acid alkyl esters (for example, linear or branched alkyl esters with the alkyl group having a carbon number of 1 to 30, particularly a carbon number of 4 to 18, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). (Meth)acrylic acid ester refers to an acrylic acid ester and/or a methacrylic acid ester, and every occurrence of (meth) has the same meaning throughout the present invention.

The acryl-based polymer may contain a unit corresponding to any other monomer component capable of being copolymerized with the (meth) acrylic acid alkyl ester or cycloalkyl ester as necessary for the purpose of modifying cohesive strength, heat resistance and so on. Examples of such monomer components include carboxyl group-containing monomers such as acrylic acid, methacrylic acid, carboxyethyl (meth)acrylate, carboxypentyl (meth)acrylate, itaconic acid, maleic acid, fumaric acid and crotonic acid, acid anhydride monomers such as maleic anhydride and itaconic anhydride, hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)methyl (meth)acrylate, sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate, and acrylamide and acrylonitrile. One or more of these monomer components capable of being copolymerized can be used. The used amount of the monomer capable of being copolymerized is preferably 40% by weight or less based on total monomer components.

Further, the acryl-based polymer may contain a polyfunctional monomer or the like as a monomer component for copolymerization as necessary for the purpose of crosslinking. Examples of such a polyfunctional monomer include hexanediol di(meth)acrylate, (poly)ethylene glycol di(meth)acrylate, (poly)propylene glycol di(meth)acrylate, neopentylglycol di(meth)acrylate, pentaerythritol di(meth)acrylate, trimethylolpropane tri(meth)acrylate, pentaerythritol tri(meth)acrylate, dipentaerythritol hexa(meth)acrylate, epoxy (meth)acrylate, polyester (meth)acrylate and urethane (meth)acrylate. One or more of these polyfunctional monomers can be used. The used amount of the polyfunctional monomer is preferably 30% by weight or less based on total monomer components for adhesion properties.

The acryl-based polymer is obtained by subjecting a single monomer or a monomer mixture of two or more kinds to polymerization. Polymerization can be carried out by any method such as solution polymerization, emulsion polymerization, bulk polymerization or suspension polymerization. The contained amount of low-molecular weight substances is preferably low for prevention of contamination of a clean adherend and so on. In this respect, the number average molecular weight of the acryl-based polymer is preferably 300000 or more, further preferably about 400000 to 3000000.

For the pressure-sensitive adhesive, an external crosslinker can also be appropriately employed for increasing the number average molecular weight of an acryl-based polymer or the like as a base polymer. Specific examples of the external crosslinking methods include a method in which a crosslinker such as a polyisocyanate compound, an epoxy compound, an aziridine compound or a melamine-based crosslinker is added and reacted. When an external crosslinker is used, the amount used thereof is appropriately determined according to a balance with a base polymer to be crosslinked, and further according to an application as a pressure-sensitive adhesive. Generally, the external crosslinker is blended in an amount of preferably about 5 parts by weight or less, further preferably 0.1 to 5 parts by weight, based on 100 parts by weight of the base polymer. Further, for the pressure-sensitive adhesive, previously known various kinds of additives, such as a tackifier and an anti-aging agent, may be used as necessary in addition to the above-mentioned components.

The pressure-sensitive adhesive layer 1b can be a radiation curable-type pressure-sensitive adhesive. By irradiating the radiation curable-type pressure-sensitive adhesive with radiation such as ultraviolet rays, the degree of crosslinking thereof can be increased to easily reduce adhesive strength, so that pickup can be easily performed. Examples of radiation include X-rays, ultraviolet rays, electron rays, α rays, β rays and neutron rays.

For the radiation curable-type pressure-sensitive adhesive, one having a radiation-curable functional group such as a carbon-carbon double bond and showing adherability can be used without particular limitation. Examples of the radiation curable-type pressure-sensitive adhesive may include an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylol propane tri(meth)acrylate, tetramethylol methane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curable-type pressure-sensitive adhesive include, besides the addition-type radiation curable pressure-sensitive adhesive described above, an intrinsic-type radiation curable pressure-sensitive adhesive using, as a base polymer, a polymer having a carbon-carbon double bond in the polymer side chain or main chain or at the end of the main chain. The intrinsic-type radiation curable pressure-sensitive adhesive is preferable because it is not required to contain, or mostly does not contain an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without any particular limitation. As such base polymer, one having an acryl-based polymer as a basic backbone is preferable. Examples of the basic backbone of the acryl-based polymer include the acryl-based polymers described previously as an example.

The method for introducing a carbon-carbon double bond into the acryl-based polymer is not particularly limited, and various methods can be employed, but it is easy in molecular design to introduce the carbon-carbon double bond into a polymer side chain. Mention is made for, for example, a method in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group and a combination of a hydroxyl group and an isocyanate group. Among these combinations of functional groups, the combination of a hydroxyl group and an isocyanate group is suitable in terms of ease of reaction tracing. The functional group may be present at the side of the acryl-based polymer and the above-mentioned compound as long as the combination of the functional groups is such a combination that the acryl-based polymer having a carbon-carbon double bond is generated, but for the preferable combination, it is preferred that the acryl-based polymer have a hydroxyl group and the above-mentioned compound have an isocyanate group. In this case, examples of the isocyanate compound having a carbon-carbon double bond include, for example methacryloyl isocyanate, 2-methacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethyl vinyl ether, 4-hydroxybutyl vinyl ether and diethylene glycol monovinyl ether, and so on is used.

For the intrinsic-type radiation curable pressure-sensitive adhesive, the base polymer (particularly acryl-based polymer) having a carbon-carbon double bond can be used alone, but the radiation curable monomer component or oligomer component can be blended to the extent of not deteriorating properties. The amount of the radiation curable oligomer or the like is normally in a range of 30 parts by weight or less, preferably in a range of 0 to 10 parts by weight, based on 100 parts by weight of the base polymer.

The radiation curable-type pressure-sensitive adhesive preferably includes a photopolymerization initiator when being cured by ultraviolet rays or the like. Examples of the photopolymerization initiator include, for example α-ketol-based compounds such as 4-(2-hydroxyethoxy)phenyl(2-hydroxy-2-propyl)ketone, α-hydroxy-α, α′-dimethylacetophenone, 2-methyl-2-hydroxypropiophenone and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds such as benzoin ethyl ether, benzoin isopropyl ether and anisoin methyl ether; ketal-based compounds such as benzyldimethylketal; aromatic sulfonyl chloride-based compounds such as 2-naphthalenesulfonyl chloride; photoactive oxime-based compounds such as 1-phenyl-1,2-propanedione-2-(O-ethoxycarbonyl)oxime; benzophenone-based compounds such as benzophenone, benzoyl benzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone and 2,4-diisopropylthioxanthone; camphorquinone; halogenated ketone; acylphosphine oxide; and acylphosphonate. The blending amount of the photopolymerization initiator is, for example, about 0.05 to 20 parts by weight based on 100 parts by weight of the base polymer such as an acryl-based polymer forming a pressure-sensitive adhesive.

When curing hindrance by oxygen occurs at the time of irradiation, it is desirable to block oxygen (air) from the surface of the radiation curable-type pressure-sensitive adhesive layer 1b by some kind of method. Examples of the method include a method in which the surface of the pressure-sensitive adhesive layer 1b is covered with a separator, and a method in which irradiation of radiation such as ultraviolet rays is carried out in a nitrogen gas atmosphere.

The pressure-sensitive adhesive layer 1b may contain various kinds of additives (e.g. colorant, thickener, bulking agent, filler, tackifier, plasticizer, anti-aging agent, antioxidant, surfactant, crosslinker, etc.) within the bounds of not impairing the effect of the present invention.

The thickness of the pressure-sensitive adhesive layer 1b is not particularly limited, but is preferably about 1 to 80 μm for prevention of chipping of a chip cut surface, and fixation and retention of an under-fill material 2, and so on. The thickness is preferably 2 to 50 μm, more preferably 5 to 35 μm.

### (Under-Fill Material)

An under-fill material 2 in this embodiment can be used as a film for sealing, which fills a space between a surface-mounted semiconductor element and an adherend. Examples of the constituent material of the under-fill material include those obtained by combining a thermoplastic resin and a thermosetting resin. A material made of a thermoplastic resin or a thermosetting resin alone can also be used.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, or a fluororesin. These thermoplastic resins can be used alone, or in combination of two or more thereof. Among these thermoplastic resins, an acrylic resin, which has less ionic impurities, has a high heat resistance and can ensure the reliability of a semiconductor element, is especially preferable.

The acrylic resin is not particularly limited, and examples thereof include polymers having as a component one or more of esters of acrylic acids or methacrylic acids which have a linear or branched alkyl group having a carbon number of 30 or less, especially a carbon number of 4 to 18. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group or an eicosyl group.

Other monomers for forming the polymer are not particularly limited, and examples thereof include carboxyl group-containing monomers such as acrylic acid, methacrylic acid, carboxyethyl acrylate, carboxypentylacrylate, itaconic acid, maleic acid, fumaric acid and crotonic acid, acid anhydride monomers such as maleic anhydride and itaconic anhydride, hydroxyl group-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate, and cyano group-containing monomers such as acrylonitrile.

Examples of the thermosetting resin include a phenol resin, an amino resin, an unsaturated polyester resin, an epoxy resin, a polyurethane resin, a silicone resin and a thermosetting polyimide resin. These resins can be used alone, or in combination of two or more thereof. Particularly, an epoxy resin containing less ionic impurities that corrode a semiconductor element is preferable. A curing agent for the epoxy resin is preferably a phenol resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type or a tetraphenylol ethane type, or an epoxy resin such as a hydantoin type, a trisglycidyl isocyanurate type or a glycidyl amine type is used. They can be used alone, or in combination of two or more thereof. Among these epoxy resins, a novolak type epoxy resin, a biphenyl type epoxy resin, a trishydroxyphenyl methane type resin or a tetraphenylol ethane type epoxy resin is especially preferable. This is because the aforementioned epoxy resins have a high reactivity with a phenol resin as a curing agent, and are excellent in heat resistance and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in combination of two or more thereof. Among these phenol resins, a phenol novolak resin and a phenol aralkyl resin are especially preferable. This is because the connection reliability of a semiconductor device can be improved.

For example, the epoxy resin and the phenol resin are preferably blended at such a blending ratio that the equivalent of the hydroxyl group in the phenol resin per one equivalent of the epoxy group in the epoxy resin component is 0.5 to 2.0 equivalents, more preferably 0.8 to 1.2 equivalents. That is, if the blending ratio of the resins falls out of the aforementioned range, the curing reaction does not proceed sufficiently, so that properties of the epoxy resin cured products are easily deteriorated.

In the present invention, an under-fill material using an epoxy resin, a phenol resin and an acrylic resin is especially preferable. These resins have less ionic impurities and have high heat resistance, and therefore can ensure the reliability of a semiconductor element. The blending ratio in this case is such that the mixed amount of the epoxy resin and the phenol resin is 10 to 200 parts by weight based on 100 parts by weight of the acrylic resin component.

A heat curing accelerating catalyst for the epoxy resin and the phenol resin is not particularly limited, and can be appropriately selected from known heat curing accelerating catalysts and used. The heat curing accelerating catalyst can be used alone, or in combination or two or more kinds. As the heat curing accelerating catalyst, for example, an amine-based curing accelerator, a phosphorus-based curing accelerator, an imidazole-based curing accelerator, a boron-based curing accelerator or phosphorus-boron-based curing accelerator can be used.

A flux may be added to the under-fill material 2 for removing an oxide film on the surface of a solder bump to facilitate mounting of a semiconductor element. The flux is not particularly limited, a previously known compound having an a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxymethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide and dihydrazide adipate. The added amount of the flux may be such an amount that the flux action is exhibited, and is normally about 0.1 to 20 parts by weight based on 100 parts by weight of the resin component contained in the under-fill material.

In this embodiment, the under-fill material 2 may be colored as necessary. In the under-fill material 2, the color shown by coloring is not particularly limited, but is preferably, for example, black, blue, red and green. For coloring, a colorant can be appropriately selected from known colorants such as pigments and dyes and used.

When the under-fill material 2 of this embodiment is preliminarily crosslinked to a certain degree, a polyfunctional compound that reacts with a functional group or the like at the end of the molecular chain of a polymer should be added as a crosslinker at the time of preparation. Consequently, adhesion properties under a high temperature can be improved to improve the heat resistance.

As the crosslinker, particularly polyisocyanate compounds such as tolylene diisocyanate, diphenylmethane diisocyanate, p-phenylene diisocyanate, 1,5-naphthalene diisocyanate and an adduct of a polyhydric alcohol and a diisocyanate are more preferable. Preferably, the added amount of the crosslinker is normally 0.05 to 7 parts by weight based on 100 parts by weight of the polymer. If the amount of crosslinker is more than 7 parts by weight, the adhering strength is reduced, thus being not preferable. On the other hand, if the amount of the crosslinker is less than 0.05 parts by weight, the cohesive strength becomes poor, thus being not preferable. Other polyfunctional compounds such as an epoxy resin may be included as necessary together with the above-mentioned polyisocyanate compound.

An inorganic filler can be appropriately blended with the under-fill material 2. Blending of the inorganic filler allows impartment of electrical conductivity, improvement of thermal conductivity, adjustment of a storage elastic modulus, and so on.

Examples of the inorganic filler include various inorganic powders made of ceramics such as silica, clay, plaster, calcium carbonate, barium sulfate, aluminum oxide, beryllium oxide, silicon carbide and silicon nitride, metals such as aluminum, copper, silver, gold, nickel, chromium, lead, tin, zinc, palladium and solder, or alloys, and carbon. They can be used alone, or in combination of two or more thereof. Above all, silica, particularly fused silica is suitably used.

The average particle diameter of the inorganic filler is not particularly limited, but is preferably in a range of 0.005 to 10 μm, more preferably in a range of 0.01 to 5 μm, further preferably in a range of 0.1 to 2.0 μm. If the average particle diameter of the inorganic filler is less than 0.005 μm, the flexibility of the under-fill material may be thereby depressed. On the other hand, if the average particle diameter is more than 10 μm, the particle diameter may be so large with respect to a gap sealed by the under-fill material that the sealing property is depressed. In the present invention, inorganic fillers having mutually different average particle diameters may be combined and used. The average particle diameter is a value determined by a photometric particle size analyzer (manufactured by HORIBA, Ltd.; Unit Name: LA-910).

The blending amount of the inorganic filler is preferably 10 to 400 parts by weight, more preferably 50 to 250 parts by weight, based on 100 parts by weight of the organic resin component. If the blending amount of the inorganic filler is less than 10 parts by weight, the storage elastic modulus may be reduced, thereby considerably deteriorating the stress reliability of a package. On the other hand, if the blending amount of the inorganic filler is more than 400 parts by weight, the fluidity of the under-fill material may be depressed, so that the under-fill material may not sufficiently fill up raised and recessed portions of the substrate or semiconductor element, thus leading to generation of voids and cracks.

Besides the inorganic filler, other additives can be blended with the under-fill material 2 as necessary. Examples of other additives include a flame retardant, a silane coupling agent and an ion trapping agent. Examples of the flame retardant include antimony trioxide, antimony pentaoxide and a brominated epoxy resin. They can be used alone, or in combination of two or more thereof. Examples of the silane coupling agent include β-(3,4-epoxycyclohexyl)ethyltrimethoxysilane, γ-glycidoxypropyltrimethoxysilane and γ-glycidoxypropylmethyldiethoxysilane. These compounds can be used alone, or in combination of two or more thereof. Examples of the ion trapping agent include a hydrotalcite and bismuth hydroxide. They can be used alone, or in combination of two or more thereof.

In this embodiment, the melt viscosity of the under-fill material at the heat pressure-bonding temperature before heat curing is preferably 20000 Pa·s or less, more preferably 100 Pa·s or more and 10000 Pa·s or less. By ensuring that the melt viscosity at the heat pressure-bonding temperature falls within the above-mentioned range, penetration of the connection member 4 (see FIG. 2A) into the under-fill material 2 can be facilitated. In addition, generation of voids at the time of electrical connection of a semiconductor element 5, and protrusion of the under-fill material 2 from a space between the semiconductor element 5 and an adherend 6 can be prevented (see FIG. 2E).

The viscosity of the under-fill material 2 at 23° C. before heat curing is preferably 0.01 MPa·s or more and 100 MPa·s or less, more preferably 0.1 MPa·s or more and 10 MPa·s or less. The under-fill material before heat curing has a viscosity in the above-mentioned range, whereby the retention property of the semiconductor wafer 3 (see FIG. 2C) at the time of back surface grinding and dicing and the handling property at the time of operation can be improved. Measurement of the viscosity can be performed in accordance with a method for measurement of a melt viscosity.

Further, the water absorption rate of the under-fill material 2 at a temperature of 23° C. and a humidity of 70% before heat curing is preferably 1% by weight or less, more preferably 0.5% by weight or less. The under-fill material 2 has such a water absorption rate as described above, whereby absorption of moisture into the under-fill material 2 can be suppressed, so that generation of voids during mounting of the semiconductor element 5 can be more efficiently suppressed. The lower limit of the water absorption rate is preferably as low as possible, and is preferably substantially 0% by weight, more preferably 0% by weight.

The thickness of the under-fill material 2 (total thickness in the case of a multiple layer) is not particularly limited, but may be about 10 μm to 100 μm when considering the strength of the under-fill material 2 and performance of filling a space between the semiconductor element 5 and the adherend 6. The thickness of the under-fill material 2 may be appropriately set in consideration of the gap between the semiconductor element 5 and the adherend 6 and the height of the connection member.

The under-fill material 2 of the sealing sheet 10 is preferably protected by a separator (not shown). The separator has a function of a protective material for protecting the under-fill material 2 until practical use. The separator is peeled off when the semiconductor wafer 3 is attached onto the under-fill material 2 of the sealing sheet. As the separator, polyethylene terephthalate (PET), polyethylene, polypropylene, or a plastic film or paper whose surface is coated with a release agent such as a fluorine-based release agent or a long-chain alkyl acrylate-based release agent can be used.

### (Method for Producing a Sealing Sheet)

The sealing sheet 10 according to this embodiment can be prepared by, for example, preparing the back-surface grinding tape 1 and the under-fill material 2 individually, and finally bonding the former and the latter together. Specifically, the sealing sheet 10 can be prepared in accordance with the following procedure.

First, the base material 1a can be film formed by a previously known film formation method. Examples of the film formation method include a calendering film formation method, a casting method in an organic solvent, an inflation extrusion method in a closed system, a T-die extrusion method, a co-extrusion method and a dry lamination method.

Next, a pressure-sensitive adhesive composition for formation of a pressure-sensitive adhesive layer is prepared. Resins, additives and so on as described in the term of the pressure-sensitive adhesive layer are blended in the pressure-sensitive adhesive composition. The prepared pressure-sensitive adhesive composition is applied onto the base material 1a to form a coating film, and the coating film is then dried (crosslinked by heating as necessary) under predetermined conditions to form the pressure-sensitive adhesive layer 1b. The coating method is not particularly limited, and examples thereof include roll coating, screen coating and gravure coating. For drying conditions, for example, the drying temperature is in a range of 80 to 150° C., and the drying time is in a range of 0.5 to 5 minutes. The pressure-sensitive adhesive layer 1b may be formed by applying a pressure-sensitive adhesive composition onto a separator to form a coating film, followed by drying the coating film under the above-mentioned drying conditions. Thereafter, the pressure-sensitive adhesive layer 1b is bonded onto the base material 1a together with the separator. Consequently, the back surface grinding tape 1 including the base material 1a and the pressure-sensitive adhesive layer 1b is prepared.

The under-fill material 2 is prepared, for example, in the following manner. First, an adhesive composition as a material for forming the under-fill material 2 is prepared. A thermoplastic component, an epoxy resin and various kinds of additives are blended in the adhesive composition as described in the term of the under-fill material.

Next, the prepared adhesive composition is applied onto a base material separator so as to obtain a predetermined thickness subsequently, so that a coating film is formed, and thereafter the coating film is dried under predetermined conditions to form an under-fill material. The coating method is not particularly limited, and examples thereof include roll coating, screen coating and gravure coating. For drying conditions, for example, the drying temperature is in a range of 70 to 160° C., and the drying time is in a range of 1 to 5 minutes. Alternatively, an adhesive composition may be applied onto a separator to form a coating film, followed by drying the coating film under the above-mentioned drying conditions to form an under-fill material. Thereafter, the under-fill material is bonded onto the base material separator together with the separator.

Subsequently, the separator is peeled off from each of the back surface grinding tape 1 and the under-fill material 2, and the tape and the under-fill material are bonded together such that the under-fill material and the pressure-sensitive adhesive layer form a bonding surface. Bonding can be performed by, for example, pressure-bonding. At this time, the lamination temperature is not particularly limited and is, for example, preferably 30 to 100° C., more preferably 40 to 80° C. The linear pressure is not particularly limited and is, for example, preferably 0.98 to 196 N/cm, more preferably 9.8 to 98 N/cm. Next, the base material separator on the under-fill material is peeled off to obtain a sealing sheet according to this embodiment.

### [Heat Pressure-Bonding Step]

In a heat pressure-bonding step, a circuit surface 3a of a semiconductor wafer 3, on which a connection member 4 is formed, and an under-fill material 2 of the sealing sheet are thermally pressure-bonded under conditions of a reduced-pressure atmosphere of 1000 Pa or less, a bonding pressure of 0.2 MPa or more and a heat pressure-bonding temperature of 40° C. or higher (see FIG. 2A).

### (Semiconductor Wafer)

A plurality of connection members 4 are formed on the circuit surface 3a of the semiconductor wafer 3 (see FIG. 2A). The material of the connection member such as a bump or electrically conductive material is not particularly limited, and examples thereof include solders (alloys) such as a tin-lead-based metal material, a tin-silver-based metal material, a tin-silver-copper-based metal material, a tin-zinc-based metal material, a tin-zinc-bismuth-based metal material, a gold-based metal material and a copper-based metal material. The height of the connection member is also determined according to an application, and is generally about 15 to 100 μm. Of course, the heights of individual connection members in the semiconductor wafer 3 may be the same or different.

In the method for producing a semiconductor device according to this embodiment, the ratio of the thickness T (μm) of the under-fill material to the height H (μm) of the connection member (T/H) is preferably 0.5 to 2, more preferably 0.8 to 1.5. The thickness T (μm) of the under-fill material and the height H (μm) of the connection member satisfy the above-mentioned relationship, whereby a space between the semiconductor element and the adherend can be sufficiently filled, and excessive protrusion of the under-fill material from the space can be prevented, so that contamination of the semiconductor element by the under-fill material, and the like can be prevented. When the heights of the respective connection members are different, the height of the highest connection member is used as the reference.

### (Bonding)

As shown in FIG. 2A, first a separator that is optionally provided on the under-fill 2 of the sealing sheet 10 is appropriately peeled off, the circuit surface 3a of the semiconductor wafer 3, on which the connection member 4 is formed, and the under-fill material 2 are made to face to each other, and the under-fill material 2 and the semiconductor wafer 3 are bonded together by heat pressure-bonding.

In this embodiment, the semiconductor wafer and the under-fill material are bonded together by heat pressure-bonding. Heat pressure-bonding can be normally performed by known pressing means such as a pressure-bonding roll. The reduced-pressure condition should be 10000 Pa or less, and is preferably 5000 Pa or less, more preferably 1000 Pa or less. The lower limit of the reduced-pressure condition is not particularly limited, but is preferably 10 Pa or more for productivity. The bonding pressure condition should be 0.2 MPa or more, and is preferably 0.2 MPa or more and 1 Ma or less, more preferably 0.4 Pa or more and 0.8 Pa or less. The condition of heat pressure-bonding temperature should be 40° C. or higher, and is preferably 40° C. or higher and 120° C. or lower, more preferably 60° C. or higher and 100° C. or lower. By performing bonding under predetermined heat pressure-bonding conditions, the under-fill material can sufficiently follow raised and recessed portions of the surface of the semiconductor wafer, so that air bubbles at an interface between the semiconductor wafer and the under-fill material can be considerably reduced to improve adhesion. Consequently, generation of voids at the interface can be suppressed, and resultantly a semiconductor device excellent in connection reliability between a semiconductor wafer and an adherend can be efficiently produced.

### [Grinding Step]

In this embodiment, a back surface grinding tape is used as a support, and therefore a grinding step is provided subsequently to the heat pressure-bonding step. In the grinding step, a surface opposite to the circuit surface 3a of the semiconductor wafer 3 (i.e. back surface) 3b is ground (see FIG. 2B). A processor for grinding the back surface of the semiconductor wafer 3 is not particularly limited, and examples thereof may include a grinding machine (back grinder) and a polishing pad. Back surface grinding may be carried out by a chemical process such as etching. Back surface grinding is carried out until the semiconductor wafer has a desired thickness (e.g. 700 to 25 μm).

### [Dicing Step]

In a dicing step, as shown in FIG. 2C, a semiconductor wafer 3 is diced to form a semiconductor element 5 with an under-fill material. Through the dicing step, the semiconductor wafer 3 is cut to a predetermined size and thereby formed into individual pieces (small pieces) to produce a semiconductor chip (semiconductor element) 5. The semiconductor chip 5 thus obtained is integrated with the under-fill material 2 cut in the same shape. Dicing is carried out from the surface 3b opposite to the circuit surface 3a of the semiconductor wafer 3, to which the under-fill material 2 is bonded, in accordance with a usual method. Alignment of cut areas can be performed by image recognition using direct light or indirect light or infrared rays (IR).

In this step, for example, a cutting method called full cut, in which cutting is made to a sealing sheet, can be employed. The dicing device used in this step is not particularly limited, and one that is previously known can be used. The semiconductor wafer is adhesively fixed with excellent adhesion by a sealing sheet having an under-fill material, so that chipping and chip fly can be suppressed, and also damage of the semiconductor wafer can be suppressed. When the under-fill material is formed from a resin composition containing an epoxy resin, protrusion of glue of the under-fill material at the cut surface can be suppressed or prevented even though the under-fill material is cut by dicing. As a result, reattachment of cut surfaces (blocking) can be suppressed or prevented, so that pickup described later can be further satisfactorily performed.

When expanding of the sealing sheet is carried out subsequently to the dicing step, the expanding can be carried out using a previously known expanding device. The expanding device has a doughnut-like outer ring capable of pushing down the sealing sheet via a dicing ring, and an inner ring having a diameter smaller than that of the outer ring and supporting the sealing sheet. Owing to the expanding step, adjacent semiconductor chips can be prevented from contacting each other and being damaged in a pickup step described later.

### [Pickup Step]

As shown in FIG. 2D, pickup of the semiconductor chip 5 with the under-fill material 2 is carried out to peel off a laminate A of the semiconductor chip 5 and the under-fill material 3 from the back surface grinding tape 1 for collecting the semiconductor chip 5 adhesively fixed on the sealing sheet.

The method for pickup is not particularly limited, and previously known various methods can be employed. Mention is made of, for example, a method in which individual semiconductor chips are pushed up by a needle from the base material side of the sealing sheet, and the semiconductor chips, which have been pushed up, are collected by a pickup device. The semiconductor chip 5, which has been picked up, is integrated with the under-fill material 2 bonded to the circuit surface 3a to form the laminate A.

Here, pickup is performed after irradiating the pressure-sensitive adhesive layer 1b with ultraviolet rays when the pressure-sensitive adhesive layer 1b is of an ultraviolet-ray curable-type. Consequently, adhesive strength of the pressure-sensitive adhesive layer 1b to the under-fill material 2 decreases, so that it becomes easy to peel off the semiconductor chip 5. As a result, pickup can be performed without damaging the semiconductor chip 5. Conditions such as an irradiation intensity and an irradiation time for irradiation of ultraviolet rays are not particularly limited, and may be appropriately set as necessary. As alight source used for irradiation of ultraviolet rays, for example, a low-pressure mercury lamp, a low-pressure high-power lamp, a medium-pressure mercury lamp, an electrodeless mercury lamp, a xenon flash lamp, an excimer lamp, an ultraviolet LED or the like can be used.

### [Mounting Process]

In a mounting process, the semiconductor element 5 and the adherend 6 are electrically connected through the connection member 4 while filling a space between the adherend 6 and the semiconductor element 5 using the under-fill material 2 (see FIG. 2E). Specifically, the semiconductor chip 5 of the laminate A is fixed to the adherend 6 in accordance with a usual method in such a form that the circuit surface 3a of the semiconductor chip 5 is made to face the adherend 6. For example, the bump (connection member)₄ formed on the semiconductor chip 5 is contacted with and pressed to an electrically conductive material 7 (solder or the like) for bonding, which is attached to the connection pad of the adherend 6, so that the electrically conductive material is melted, whereby electrical connection between the semiconductor chip 5 and the adherend 6 can be secured to fix the semiconductor chip 5 to the adherend 6. Since the under-fill material 2 is bonded to the circuit surface 3a of the semiconductor chip 5, a space between the semiconductor chip 5 and the adherend 6 is filled with the under-fill material 2 concurrently with melted electrically conductive material forming the electrical connection between the semiconductor chip 5 and the adherend 6.

Generally, in the mounting process, the temperature is 100 to 300° C. as a heating condition, and the pressure is 0.5 to 500 N as a pressing condition. A heating and pressing treatment in the mounting process may be carried out in multiple stages. For example, such a procedure can be employed in that a treatment is carried out at 150° C. and 100 N for 10 seconds, followed by carrying out a treatment at 300° C. and 100 to 200 N for 10 seconds. By carrying out the heating and pressing treatment in multiple stages, a resin between the connection member and the pad can be efficiently removed to obtain a better metal-metal joint.

As the adherend 6, a lead frame, and various kinds of substrates such as a circuit substrate (such as a wiring circuit substrate), and other semiconductor elements can be used. Examples of the material of the substrate include, but are not limited to, a ceramic substrate and a plastic substrate. Examples of the plastic substrate include an epoxy substrate, a bismaleimide triazine substrate, a polyimide substrate and a glass epoxy substrate.

In the mounting process, one or both of the connection member and the electrically conductive material are melted to connect the bump 4 of the connection member forming surface, circuit surface 3a, of the semiconductor chip 5 and the electrically conductive material 7 on the surface of the adherend 6, and the temperature at which the bump 4 and the electrically conductive material 7 are melted is normally about 260° C. (for example 250° C. to 300° C.). The sealing sheet according to this embodiment can be made to have a heat resistance such that it can endure a high temperature in the mounting process, by forming the under-fill material 2 from an epoxy resin or the like.

### [Under-Fill Material Curing Step]

After performing electrical connection between the semiconductor element 5 and the adherend 6, the under-fill material 2 is cured by heating. Consequently, the surface of the semiconductor element 5 can be protected, and connection reliability between the semiconductor element 5 and the adherend 6 can be ensured. The heating temperature for curing the under-fill material is not particularly limited, and may be about 150 to 250° C. If the under-fill material is cured by a heating treatment in the mounting process, this step can be omitted.

### [Sealing Step]

Next, a sealing step may be carried out for protecting the entire semiconductor device 20 including the mounted semiconductor chip 5. The sealing step is carried out using a sealing resin. The sealing conditions at this time are not particularly limited, and normally the sealing resin is heat-cured by heating at 175° C. for 60 seconds to 90 seconds, but the present invention is not limited thereto and, for example, the sealing resin may be cured at 165° C. to 185° C. for several minutes.

The sealing resin is not particularly limited as long as it is a resin having an insulating property (insulating resin), and can be selected from sealing materials such as known sealing resins and used, but an insulating resin having elasticity is more preferable. Examples of the sealing resin include a resin composition containing an epoxy resin. Examples of the epoxy resin include the epoxy resins described previously as an example. The sealing resin by the resin composition containing an epoxy resin may contain, as a resin component, a thermosetting resin (phenol resin, etc.), a thermoplastic resin and so on in addition to an epoxy resin. The phenol resin can also be used as a curing agent for the epoxy resin, and examples of such a phenol resin include the phenol resins described previously as an example.

### [Semiconductor Device]

A semiconductor device obtained using the sealing sheet will now be described with reference to the drawings (see FIG. 2E). In the semiconductor device 20 according to this embodiment, the semiconductor element 5 and the adherend 6 are electrically connected through the bump (connection member) 4 formed on the semiconductor element 5 and the electrically conductive material 7 provided on the adherend 6. The under-fill material 2 is placed between the semiconductor element 5 and the adherend 6 so as to fill a space therebetween. The semiconductor device 20 is obtained by the above-mentioned production method using the sealing sheet 10, and therefore generation of voids is suppressed between the semiconductor element 5 and the under-fill material 2. Thus, protection of the surface of the semiconductor element 5 and filling of a space between the semiconductor element 5 and the adherend 6 are kept at an adequate level, so that high reliability can be exhibited as the semiconductor device 20.

### Second Embodiment

In this embodiment, a bonding step of bonding together a circuit surface 3a of a semiconductor wafer 3, on which a connection member 4 is formed, and an under-fill material 2 of the sealing sheet 10 under a reduced pressure of 1000 Pa or less (see FIG. 2A) may be employed in place of the heat pressure-bonding step in the first embodiment. Except for this modification, a predetermined semiconductor device can be produced through the same steps as in the first embodiment, but other preferred aspects will be described.

The method for bonding is not particularly limited, but a method by pressure-bonding is preferable. Pressure-bonding is carried out normally by pressing the semiconductor wafer and the sealing sheet under a load of pressure of preferably 0.1 to 1 MPa, more preferably 0.2 to 0.7 MPa, by known pressing means such as a pressure-bonding roll. At this time, pressure-bonding may be performed while heating to about 40 to 100° C.

In this embodiment, the semiconductor wafer and the under-fill material are bonded together under a reduced pressure of 1000 Pa or less. The upper limit of the reduced-pressure condition is preferably 500 Pa or less, more preferably 300 Pa or less. The lower limit of the reduced-pressure condition is not particularly limited, but is preferably 10 Pa or more in terms of productivity. By performing bonding under predetermined reduced-pressure conditions, air bubbles at an interface between the semiconductor wafer and the under-fill material can be considerably reduced to improve adhesion, whereby generation of voids at the interface can be suppressed. As a result, a semiconductor device excellent in connection reliability between a semiconductor wafer and an adherend can be efficiently produced.

In the method for producing a semiconductor device according to this embodiment, as the thickness of the under-fill material, the height X (μm) of the connection member formed on the surface of the semiconductor wafer and the thickness Y (μm) of the under-fill material preferably satisfy the following relationship: 0.5≦Y/X≦2.

The height X (μm) of the connection member and the thickness Y (μm) of the under-fill material satisfy the above relationship, whereby a space between the semiconductor element and the adherend can be sufficiently filled, and excessive protrusion of the under-fill material from the space can be prevented, so that contamination of the semiconductor element by the under-fill material, and so on can be prevented. When the heights of the respective connection members are different, the height of the highest connection member is used as the reference.

In this embodiment, the minimum melt viscosity of the under-fill material 2 at 100 to 200° C. before heat curing is preferably 100 Pa·s or more and 20000 Pa·s or less, more preferably 1000 Pa·s or more and 10000 Pa·s or less. By ensuring that the minimum melt viscosity falls within the above-mentioned range, penetration of the connection member 4 (see FIG. 2A) into the under-fill material 2 can be facilitated. In addition, generation of voids at the time of electrical connection of the semiconductor element 5, and protrusion of the under-fill material 2 from a space between the semiconductor element 5 and the adherend 6 can be prevented (see FIG. 2E).

### Third Embodiment

In the first embodiment, aback surface grinding tape is used as a support, whereas in this embodiment, a dicing tape including a base material and a pressure-sensitive adhesive layer laminated on the base material is used as a support. In this case, a predetermined semiconductor device can be produced through the same steps as in the first embodiment and the second embodiment except that a semiconductor wafer having an intended thickness is used to omit the grinding step (i.e. steps in FIGS. 2B to 2E excluding the step in FIG. 2A).

### Fourth Embodiment

In the first embodiment, aback surface grinding tape is used as a support, whereas in this embodiment, a base material is used alone as a support without providing a pressure-sensitive adhesive layer. Thus, a sealing sheet of this embodiment has such a form that an under-fill material is laminated on the base material. In this embodiment, the grinding step can optionally be carried out, but irradiation of ultraviolet rays before the pickup step is not carried out because the pressure-sensitive adhesive layer is omitted. Except for these modifications, a predetermined semiconductor device can be produced through the same steps as in the first embodiment and the second embodiment.

### EXAMPLES

Preferred Examples of the present invention will be illustratively described in detail below. However, for the materials, the blending amounts, and so on described in the Examples, the scope of the present invention is not intended to be limited thereto unless definitely specified. The part(s) means “part (s) by weight”.

### Examples According to First Embodiment

### Example 1

### Preparation of Sealing Sheet

56 parts of an epoxy resin 1 (trade name: “Epicoat 1004” manufactured by JER Corporation), 19 parts of an epoxy resin 2 (trade name: “Epicoat 828” manufactured by JER Corporation), 75 parts of a phenol resin (trade name “Mirex XLC-4L” manufactured by Mitsui Chemicals, Incorporated), 167 parts of spherical silica (trade name “SO-25R” manufactured by Admatechs), 1.3 parts of an organic acid (trade name “Orthoanisic Acid” manufactured by Tokyo Chemical Industry Co., Ltd.) and 1.3 parts of an imidazole catalyst (trade name “2PHZ-PW” manufactured by Shikoku Chemicals Corporation) based on 100 parts of an acrylic acid ester-based polymer including ethyl acrylate-methyl methacrylate as its main component (trade name “Paraclone W-197CM” manufactured by Negami Chemical Industrial Co., Ltd.) were dissolved in methyl ethyl ketone to prepare an adhesive composition solution having a solid concentration of 23.6% by weight.

The adhesive composition solution was applied onto a release-treated film made of a silicone release-treated polyethylene terephthalate film having a thickness of 50 μm as a release liner (separator), and dried at 130° C. for 2 minutes to thereby prepare an under-fill material having a thickness of 45 μm.

The under-fill material was bonded onto a pressure-sensitive adhesive layer of a back grind tape (trade name “UB-2154” manufactured by Nitto Denko Corporation) using a hand roller to prepare a sealing sheet.

### (Manufacturing of Semiconductor Device)

A silicon wafer with bumps on one surface, in which bumps were formed on one surface, was provided, and the prepared sealing sheet was bonded to a surface of the silicon wafer with bumps on one surface, on which the bumps were formed, with the under-fill material as a bonding surface. As the silicon wafer with bumps on one surface, the following article was used. Heat pressure-bonding conditions were as follows. The ratio of the thickness Y (=45 μm) of the under-fill material to the height X (=45 μm) of a connection member (Y/X) was 1.

<Silicon Wafer with Bumps on One Surface>
Diameter of silicon wafer: 8 inches
Thickness of silicon wafer: 0.7 mm (700 μm)
Height of bump: 45 μm
Pitch of bump: 50 μm
Material of bump: SnAg solder+copper pillar

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 80° C.
Pressure reduction degree at the time of bonding: 150 Pa

A silicon wafer with bumps on one surface and a sealing sheet were bonded together in accordance with the procedure described above, followed by grinding the back surface of the silicon wafer under the following conditions.

<Grinding Conditions>

Grinding apparatus: trade name “DFG-8560” manufactured by DISCO Corporation
Semiconductor wafer: back surface ground from a thickness of 0.7 mm (700 μm) to 0.2 mm (200 μm)

Next, the semiconductor wafer was diced under the following conditions. Dicing was performed by full cut so as to have a chip size of 7.3 mm×7.3 mm.

<Dicing Conditions>

Dicing device: trade name “DFD-6361” manufactured by DISCO Corporation
Dicing ring: “2-8-1” (manufactured by DISCO Corporation)
Dicing speed: 30 mm/sec
Dicing blade:
Z1; “2030-SE 27HCDD” manufactured by DISCO Corporation
Z2; “2030-SE 27HCBB” manufactured by DISCO Corporation
Dicing blade rotation number:

### Z1; 40000 rpm

### Z2; 40000 rpm

Cut mode: step cut
Wafer chip size: 7.3 mm×7.3 mm

Next, a laminate of an under-fill material and a semiconductor chip with bumps on one surface was picked up by a push-up method with a needle from the base material side of each sealing sheet. Pickup conditions were as follows.

<Pickup Conditions>

Pickup device: trade name “SPA-300” manufactured by SHINKAWA LTD.
The number of needles: 9
Needle push-up amount: 500 μm (0.5 mm)
Needle push-up speed: 20 mm/second
Pickup time: 1 second
Expanding amount: 3 mm

Finally, the semiconductor chip was mounted onto a BGA (Ball Grid Array) substrate under the following mounting conditions in the state that the bump forming surface of the semiconductor chip and the BGA substrate were made to face to each other. Consequently, a semiconductor device with a semiconductor chip mounted on a BGA substrate was obtained. In this step, a two-stage process under the mounting condition 1 and then under the mounting condition 2 was carried out.

<Mounting condition 1>
Pickup device: trade name “FCB-3” manufactured by Panasonic Corporation
Heating temperature: 150° C.

### Load: 98 N

Retention time: 10 seconds

<Mounting condition 2>

Pickup device: trade name “FCB-3” manufactured by Panasonic Corporation
Heating temperature: 260° C.

### Load: 98 N

Retention time: 10 seconds

### Example 2

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 80° C.
Pressure reduction degree at the time of bonding: 1000 Pa

### Example 3

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 80° C.
Pressure reduction degree at the time of bonding: 10000 Pa

### Example 4

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.2 MPa
Stage temperature at the time of bonding (heat pressure-bonding temperature): 80° C.
Pressure reduction degree at the time of bonding: 150 Pa

### Example 5

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 1.0 MPa
Stage temperature at the time of bonding (heat pressure-bonding temperature): 80° C.
Pressure reduction degree at the time of bonding: 150 Pa

### Example 6

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 40° C.
Pressure reduction degree at the time of bonding: 150 Pa

### Example 7

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 120° C.
Pressure reduction degree at the time of bonding: 150 Pa

### Example 8

A semiconductor device was manufactured in the same manner as in Example 1 except that a back grind tape was not bonded to an under-fill material, and a laminate of a release film and an under-fill material was used as a sealing sheet.

### Comparative Example 1

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 80° C.
Pressure reduction degree at the time of bonding: 20000 Pa

### Comparative Example 2

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.05 MPa
Stage temperature at the time of bonding (heat pressure-bonding temperature): 80° C.
Pressure reduction degree at the time of bonding: 150 Pa

### Comparative Example 3

A semiconductor device was manufactured in the same manner as in Example 1 except that a semiconductor wafer and an under-fill material were bonded together under the following heat pressure-bonding conditions.

<Heat Pressure-Bonding Conditions>

Bonding apparatus: trade name “DSA840-WS” manufactured by NITTO SEIKI CO., LTD.
Bonding rate: 5 mm/min
Bonding pressure: 0.5 MPa
Stage temperature at the time of bonding (heat pressure-bonding temperature): 25° C.
Pressure reduction degree at the time of bonding: 150 Pa

### (Measurement of Melt Viscosity)

The melt viscosity at the time of the heat pressure-bonding of an under-fill material (before heat curing) was measured in each of the Examples and Comparative Examples. The measurement of the minimum melt viscosity was a value measured by a parallel plate method using a rheometer (RS-1 manufactured by HAAKE, INC.). More specifically, the melt viscosity was measured in a range from 20° C. to 200° C. under conditions of, gap: 100 μm; rotation plate diameter: 20 mm; rotation speed: 10 s⁻¹; and temperature rise rate: 10° C./minute, and the melt viscosity at each heat pressure-bonding temperature obtained at this time was read. The results are shown in Table 1.

### (Evaluation for Generation of Voids)

An evaluation for generation of voids was performed in such a manner that the semiconductor device manufactured in each of the Examples and Comparative Examples was cut between the semiconductor chip and the under-fill material, the cut surface was observed using an image recognition device (trade name “C9597-11” manufactured by Hamamatsu Photonics K.K.), and a ratio of the total area of void portions to the area of the under-fill material was calculated. The ratio of the total area of void portions to the area of the under-fill material in the observed image of the cut surface was determined, and “◯” was assigned when the ratio was 0 to 5%, “Δ” was assigned when the ratio was more than 5% and 25% or less, and “x” was assigned when the ratio was more than 25%. The results are shown in Table 1.

TABLE 1

| | Exam- | Exam- | Exam- | Exam- | Exam- | Exam- | Exam- | Exam- | Comparative | Comparative | Comparative |
|---|---|---|---|---|---|---|---|---|---|---|---|
| | ple 1 | ple 2 | ple 3 | ple 4 | ple 5 | ple 6 | ple 7 | ple 8 | Example 1 | Example 2 | Example 3 |
| Pressure | 150 | 1000 | 10000 | 150 | 150 | 150 | 150 | 150 | 20000 | 150 | 150 |
| reduction degree | | | | | | | | | | | |
| in heat | | | | | | | | | | | |
| pressure-bonding | | | | | | | | | | | |
| step [Pa] | | | | | | | | | | | |
| Bonding Pressure | 0.5 | 0.5 | 0.5 | 0.2 | 1.0 | 0.5 | 0.5 | 0.5 | 0.5 | 0.05 | 0.5 |
| in heat | | | | | | | | | | | |
| pressure-bonding | | | | | | | | | | | |
| step [MPa] | | | | | | | | | | | |
| Heat | 80 | 80 | 80 | 80 | 80 | 40 | 120 | 80 | 80 | 80 | 25 |
| pressure-bonding | | | | | | | | | | | |
| temperature [° C.] | | | | | | | | | | | |
| Melt viscosity at | 5320 | 5320 | 5320 | 5320 | 5320 | 16800 | 1350 | 5320 | 5320 | 5320 | 25500 |
| heat | | | | | | | | | | | |
| pressure-bonding | | | | | | | | | | | |
| temperature | | | | | | | | | | | |
| [Pa · s] | | | | | | | | | | | |
| Evaluation for | ∘ | ∘ | ∘ | ∘ | ∘ | ∘ | ∘ | ∘ | x | x | x |
| generation of | | | | | | | | | | | |
| voids | | | | | | | | | | | |

As apparent from Table 1, in the semiconductor devices of Examples 1-8, generation of voids was suppressed. On the other hand, in the semiconductor devices of Comparative Examples 1-3, voids were generated. It can be considered that air bubbles between the semiconductor wafer and the under-fill material were not sufficiently reduced, because the pressure reduction degree was low with the reduced-pressure condition being more than 10000 Pa for Comparative Example 1, the bonding pressure condition was low, i.e. less than 0.2 MPa for Comparative Example 2, and the heat pressure-bonding temperature was low, i.e. lower than 40° C. for Comparative Example 3, leading eventually to generation of voids. Thus, it is apparent that by thermally pressure-bonding the semiconductor wafer and the under-fill material under conditions of a reduced-pressure atmosphere of 10000 Pa or less, a bonding pressure of 0.2 MPa or more, and a heat pressure-bonding temperature of 40° C. or higher as a process for producing a semiconductor device, a high-reliability semiconductor device in which generation of voids is suppressed can be produced.

### Examples According to Second Embodiment

### Example 1

A sealing sheet and a semiconductor device were manufactured in the same manner as in Example 1 of the first embodiment.

### Example 2

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 1000 Pa

### Example 3

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 100 Pa

### Comparative Example 1

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 1100 Pa

### Comparative Example 2

A semiconductor device was manufactured in the same manner as in Example 1 except that the pressure was not reduced when bonding of the semiconductor wafer and the under-fill material (i.e. bonding was performed under an atmospheric pressure).

### (Measurement of Minimum Melt Viscosity)

The minimum melt viscosity of an under-fill material (before heat curing) was measured. The measurement of the minimum melt viscosity was a value measured by a parallel plate method using a rheometer (RS-1 manufactured by HAAKE, INC.). More specifically, the melt viscosity was measured in a range from 60° C. to 200° C. under conditions of, gap: 100 μm; rotation plate diameter: 20 mm; rotation speed: 10 s⁻¹; and temperature rise rate: 10° C./minute, and the minimum value of melt viscosities in a range from 100° C. to 200° C., obtained at this time was designated as a minimum melt viscosity. The results are shown in Table 2.

### (Evaluation for Generation of Voids)

An evaluation for generation of voids was performed in such a manner that the semiconductor device manufactured in each of the Examples and Comparative Examples was cut between the semiconductor chip and the under-fill material, the cut surface was observed using an image recognition device (trade name “C9597-11” manufactured by Hamamatsu Photonics K.K.), and a ratio of the total area of void portions to the area of the under-fill material was calculated. The ratio of the total area of void portions to the area of the under-fill material in the observed image of the cut surface was determined, and “◯” was assigned when the ratio was 0 to 5%, “Δ” was assigned when the ratio was more than 5% and 25% or less, and “x” was assigned when the ratio was more than 25%. The results are shown in Table 2.

TABLE 2

| | | | | Compar- | Compar- |
|---|---|---|---|---|---|
| | Exam- | Exam- | Exam- | ative | ative |
| | ple 1 | ple 2 | ple 3 | Example 1 | Example 2 |
| Pressure | 150 | 1000 | 100 | 1100 | — |
| reduction | | | | | (Atmospheric |
| degree in | | | | | pressure) |
| bonding step | | | | | |
| [Pa] | | | | | |
| Minimum | 5320 | 5320 | 5320 | 5320 | 5320 |
| melt viscosity | | | | | |
| [Pa · s] | | | | | |
| Evaluation for | ∘ | ∘ | ∘ | Δ | x |
| generation of | | | | | |
| voids | | | | | |

As apparent from Table 2, in the semiconductor devices of Examples 1-3, generation of voids was suppressed. On the other hand, in the semiconductor devices of Comparative Examples 1 and 2, voids were generated. It can be considered that air bubbles between the semiconductor wafer and the under-fill material were not sufficiently reduced, because the reduced-pressure condition was more than 1000 Pa for Comparative Example 1, and a pressure reduction treatment was not carried out for Comparative Example 2, leading eventually to generation of voids. Thus, it is apparent that by bonding the semiconductor wafer and the under-fill material together under a reduced pressure of 1000 Pa or less as a process for producing a semiconductor device, a high-reliability semiconductor device in which generation of voids is suppressed can be produced.

### Examples According to Third Embodiment

### Example 1

The under-fill material prepared in Example 1 of the first embodiment was bonded onto a pressure-sensitive adhesive layer of a dicing tape (trade name “V-8-T” manufactured by Nitto Denko Corporation) using a hand roller to prepare a sealing sheet.

### (Manufacturing of Semiconductor Device)

A silicon wafer with bumps on one surface, in which bumps were formed on one surface, was provided, and the prepared sealing sheet was bonded to a surface of the silicon wafer with bumps on one surface, on which the bumps were formed, with the under-fill material as a bonding surface. As the silicon wafer with bumps on one surface, the following article was used. Bonding conditions were as follows. The ratio of the thickness Y (=45 μm) of the under-fill material to the height X (=45 μm) of a connection member (Y/X) was 1.

<Silicon Wafer with Bumps on One Surface>

Diameter of silicon wafer: 8 inches
Thickness of silicon wafer: 0.2 mm (200 μm)
Height of bump: 45 μm
Pitch of bump: 50 μm
Material of bump: solder+copper pillar

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 150 Pa

Next, the silicon wafer with bumps on one surface and the sealing sheet were bonded together in accordance with the procedure described above, and then the semiconductor wafer was diced under the following conditions. Dicing was performed by full cut so as to have a chip size of 7.3 mm×7.3 mm.

<Dicing Conditions>

Dicing device: trade name “DFD-6361” manufactured by DISCO Corporation
Dicing ring: “2-8-1” (manufactured by DISCO Corporation)
Dicing speed: 30 mm/sec
Dicing blade:
Z1; “2030-SE 27HCDD” manufactured by DISCO Corporation
Z2; “2030-SE 27HCBB” manufactured by DISCO Corporation
Dicing blade rotation number:

### Z1; 40000 rpm

### Z2; 45000 rpm

Cut mode: step cut
Wafer chip size: 7.3 mm×7.3 mm

Subsequently, pickup and heat pressure-bonding of the semiconductor chip were performed under the same conditions as in Example 1 of the first embodiment to obtain a semiconductor device.

### Example 2

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 1000 Pa

### Example 3

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.
Bonding rate: 5 mm/min
Bonding pressure: 0.25 MPa
Stage temperature at the time of bonding: 80° C.
Pressure reduction degree at the time of bonding: 100 Pa

### Comparative Example 1

A semiconductor device was manufactured in the same manner as in Example 1 except that a semiconductor wafer and an under-fill material were bonded together under the following bonding conditions.

<Bonding Conditions>

Bonding apparatus: trade name “DSA840-WS” manufactured by NITTO SEIKI CO., LTD.

Bonding rate: 5 mm/min
Bonding pressure: 0.25 MPa
Stage temperature at the time of bonding: 80° C.
Pressure reduction degree at the time of bonding: 1100 Pa

### Comparative Example 2

A semiconductor device was manufactured in the same manner as in Example 1 except that the pressure was not reduced when bonding of the semiconductor wafer and the under-fill material (i.e. bonding was performed under an atmospheric pressure).

### (Measurement of Minimum Melt Viscosity)

The minimum melt viscosity of an under-fill material (before heat curing) was measured. The measurement of the minimum melt viscosity was a value measured by a parallel plate method using a rheometer (RS-1 manufactured by HAAKE, INC.). More specifically, the melt viscosity was measured in a range from 60° C. to 200° C. under conditions of gap: 100 μm; rotation plate diameter: 20 mm; rotation speed: 10 s⁻¹; and temperature rise rate: 10° C./minute, and the minimum value of melt viscosities in a range from 100° C. to 200° C., obtained at this time was designated as a minimum melt viscosity. The results are shown in Table 3.

### (Evaluation for Chip Fly at the Time of Dicing)

20 samples were used, and the retention property of the semiconductor chip was evaluated on the basis of presence/absence of chip fly in such a manner that “◯” was assigned when chip fly of the semiconductor chip did not occur at the time of dicing and “x” was assigned when chip fly occurred. The results are shown in Table 3.

### (Evaluation of Pickup Performance)

20 samples were used, and pickup performance was evaluated in such a manner “◯” was assigned when all semiconductor chips could be picked up at the time of pickup and “x” was assigned when one or more semiconductor chips could not be picked up.

### (Evaluation for Generation of Voids)

An evaluation for generation of voids was performed in such a manner that the semiconductor device manufactured in each of the Examples and Comparative Examples was cut between the semiconductor chip and the under-fill material, the cut surface was observed using an image recognition device (trade name “C9597-11” manufactured by Hamamatsu Photonics K.K.), and a ratio of the total area of void portions to the area of the under-fill material was calculated. The ratio of the total area of void portions to the area of the under-fill material in the observed image of the cut surface was determined, and “◯” was assigned when the ratio was 0 to 5%, “Δ” was assigned when the ratio was more than 5% and 25% or less, and “x” was assigned when the ratio was more than 25%. The results are shown in Table 3.

TABLE 3

| | | | | Compar- | Compar- |
|---|---|---|---|---|---|
| | Exam- | Exam- | Exam- | ative | ative |
| | ple 1 | ple 2 | ple 3 | Example 1 | Example 2 |
| Pressure | 150 | 1000 | 100 | 1100 | — |
| reduction | | | | | (Atmospheric |
| degree in | | | | | pressure) |
| bonding step | | | | | |
| [Pa] | | | | | |
| Evaluation | ∘ | ∘ | ∘ | ∘ | ∘ |
| for chip fly | | | | | |
| Pickup | ∘ | ∘ | ∘ | ∘ | ∘ |
| performance | | | | | |
| Minimum melt | 5320 | 5320 | 5320 | 5320 | 5320 |
| viscosity | | | | | |
| [Pa · s] | | | | | |
| Evaluation for | ∘ | ∘ | ∘ | Δ | x |
| generation of | | | | | |
| voids | | | | | |

As apparent from Table 3, in the process of producing a semiconductor device according to Examples 1-3, chip fly at the time of dicing was suppressed, satisfactory pickup performance was shown, and generation of voids was suppressed. On the other hand, in the process of producing a semiconductor device according to Comparative Examples 1 and 2, results of evaluations for chip fly and pickup performance were satisfactory, but voids were generated. It can be considered that air bubbles between the semiconductor wafer and the under-fill material were not sufficiently reduced, because the reduced-pressure condition was more than 1000 Pa for Comparative Example 1, and a pressure reduction treatment was not carried out for Comparative Example 2, leading eventually to generation of voids. Thus, it is apparent that by bonding the semiconductor wafer and the under-fill material together under a reduced pressure of 1000 Pa or less as a process for producing a semiconductor device, a high-reliability semiconductor device in which generation of voids is suppressed can be produced.

What is claimed is:

1. A method for producing a semiconductor device having an adherend, a semiconductor element electrically connected to the adherend, and an under-fill material for filling a space between the adherend and the semiconductor element, wherein the method comprises:
a providing step of providing a sealing sheet having a support and an under-fill material laminated on the support;
a heat pressure-bonding step of thermally pressure-bonding a circuit surface of a semiconductor wafer, on which a connection member is formed, and the under-fill material of the sealing sheet under conditions of a reduced-pressure atmosphere of 10000 Pa or less, a bonding pressure of 0.2 MPa or more and a heat pressure-bonding temperature of 40° C. or higher;
a dicing step of dicing the semiconductor wafer to form a semiconductor element with the under-fill material; and
a connection step of electrically connecting the semiconductor element and the adherend through the connection member while filling the space between the adherend and the semiconductor element using the under-fill material.

2. The method for producing the semiconductor device according to claim 1, wherein substantially no air bubbles are present at an interface between the semiconductor wafer and the under-fill material after the heat pressure-bonding step.

3. The method for producing the semiconductor device according to claim 1, wherein the heat pressure-bonding step is carried out under conditions of a reduced-pressure atmosphere of 10 to 10000 Pa, a bonding pressure of 0.2 to 1 MPa and a heat pressure-bonding temperature of 40 to 120° C.

4. The method for producing a semiconductor device according to claim 1, wherein a melt viscosity of the under-fill material at the heat pressure-bonding temperature before heat curing is 20000 Pa·s or less.

5. The method for producing the semiconductor device according to claim 1, wherein the under-fill material contains a thermoplastic resin and a thermosetting resin.

6. The method for producing the semiconductor device according to claim 5, wherein the thermoplastic resin contains an acrylic resin, and the thermosetting resin contains an epoxy resin and a phenol resin.

7. The method for producing the semiconductor device according to claim 1, wherein a ratio of a thickness T (μm) of the under-fill material to a height H (μm) of the connection member (T/H) is 0.5 to 2.

8. The method for producing the semiconductor device according to claim 1, wherein the support is a base material.

9. The method for producing the semiconductor device according to claim 1, wherein the support is a back surface grinding tape or dicing tape having the base material and a pressure-sensitive adhesive layer laminated on the base material.
